(19) United States
(12) Patent Application Publication
(10) Pub. No.: US 2025/0149518 A1
(43) Pub. Date: May 8, 2025

(54) SEMICONDUCTOR PACKAGE

(71) Applicant: Samsung Electronics Co., Ltd., Suwon-si (KR)

(72) Inventors: Yejin LEE, Suwon-si (KR); Dahee KIM, Suwon-si (KR); Jaeseong KIM, Suwon-si (KR); Jeongseok KIM, Suwon-si (KR); Taewook KIM, Suwon-si (KR); Gyujin CHOI, Suwon-si (KR); Jooyoung CHOI, Suwon-si (KR); Sangseok HONG, Suwon-si (KR)

(73) Assignee: Samsung Electronics Co., Ltd., Suwon-si (KR)

(21) Appl. No.: 18/744,994

(22) Filed: Jun. 17, 2024

(30) Foreign Application Priority Data
Nov. 6, 2023 (KR) 10-2023-0151942

(51) Int. Cl. H01L 25/16; H01L 23/00; H01L 23/13; H01L 23/31; H01L 23/498

(52) U.S. Cl. CPC H01L 25/16; H01L 23/13; H01L 23/3107; H01L 23/3157; H01L 23/49816; H01L 24/16; H01L 24/32; H01L 24/83; H01L 2224/16227; H01L 2224/32111; H01L 2224/8314; H01L 2924/12; H01L 2924/19106

(57) ABSTRACT

Provided is a semiconductor package including a first redistribution layer, a semiconductor device on the first redistribution layer, a substrate protection layer below the first redistribution layer, a groove in a bottom surface of the substrate protection layer, a passive device in the groove, an underfill between the passive device and the groove, and a dam apart from the passive device, the dam protruding from the substrate protection layer and at least partially surrounding the passive device.

### CROSS-REFERENCE TO RELATED APPLICATION

This application is based on and claims priority under 35 U.S.C. § 119 to Korean Patent Application No. 10-2023-0151942, filed on Nov. 6, 2023, in the Korean Intellectual Property Office, the disclosure of which is incorporated by reference herein in its entirety.

### BACKGROUND

Inventive concepts relate to a semiconductor package, and for example, to a semiconductor package including a core layer.

Due to the rapid development of the electronics industry and demands of users, electronic devices are becoming smaller and lighter. As electronic devices are becoming smaller and lighter, semiconductor packages used therein are also becoming smaller and lighter, and such a semiconductor package is sought after to have high reliability, high performance, and large capacity. As semiconductor packages become more high-performance and high-capacity semiconductor packages, silicon capacitors are used for existing ceramic land side capacitors (LSCs). Silicon capacitors are mounted on pads through bumps and underfills are used, and thus enhanced reliability at the package level is demanded.

### SUMMARY

Inventive concepts relate to a semiconductor package capable of improved reliability at the package level, and to a method of manufacturing thereof.

In addition, technical goals to be achieved by inventive concepts are not limited to the technical goals mentioned above, and other technical goals may be clearly understood by one of ordinary skill in the art from the following descriptions.

According to an aspect of inventive concepts, there is provided an semiconductor package including a first redistribution layer, a semiconductor device on the first redistribution layer, a substrate protection layer below the first redistribution layer, a groove in a bottom surface of the substrate protection layer, a passive device in the groove of the substrate protection layer, an underfill between the passive device and the groove, and a dam spaced apart from the passive device, the dam protruding from the substrate protection layer and at least partially surrounding the passive device.

According to another aspect of inventive concepts, there is provided a semiconductor package including a first redistribution layer, a semiconductor device on the first redistribution layer, a substrate protection layer below the first redistribution layer, a groove in a bottom surface of the substrate protection layer, a passive device in the groove of the substrate protection layer, and an underfill between the passive device and the groove.

According to another aspect of inventive concepts, there is provided a semiconductor package including a first redistribution layer, a semiconductor device on the first redistribution layer, a support member defining a through-hole region wherein the semiconductor device is located, a sealing member in the through-hole region and covering the semiconductor device, a substrate protection layer below the first redistribution layer, a groove defined by a bottom surface of the substrate protection layer, a passive device in the groove of the substrate protection layer, an underfill between the passive device and the groove, and a dam apart from the passive device, the dam protruding from the substrate protection layer and at least partially surrounding the passive device.

### BRIEF DESCRIPTION OF THE DRAWINGS

Example embodiments of the inventive concept will be more clearly understood from the following detailed description taken in conjunction with the accompanying drawings in which:

FIG. 1A is a cross-sectional view of a semiconductor package according to some example embodiments;

FIG. 1B is an enlarged view of a region A of FIG. 1A;

FIG. 2 is a cross-sectional view of a semiconductor package according to some example embodiments;

FIG. 3 is a cross-sectional view of a semiconductor package according to some example embodiments;

FIG. 4 is a cross-sectional view of a semiconductor package according to some example embodiments;

FIG. 5 is a cross-sectional view of a semiconductor package according to some example

embodiments; and

FIGS. 6A to 6K are schematic plan views of operations of a method of manufacturing a semiconductor package, according to an some example embodiments.

### DETAILED DESCRIPTION OF THE EMBODIMENTS

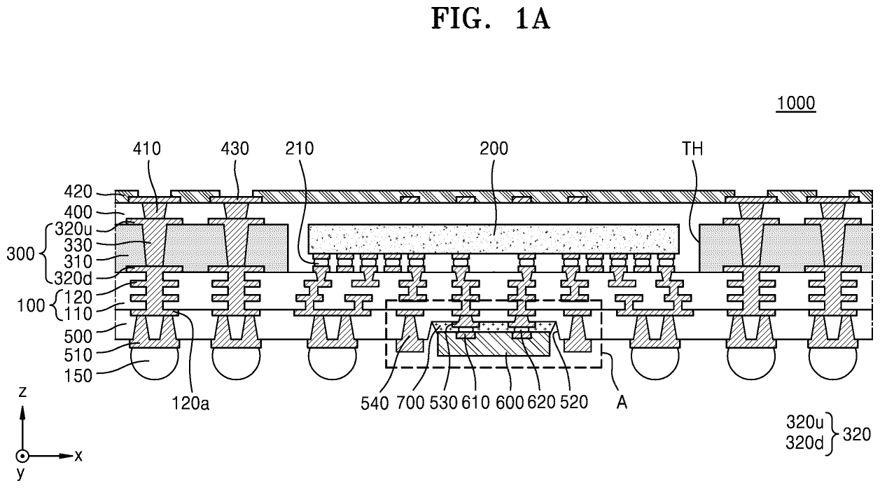

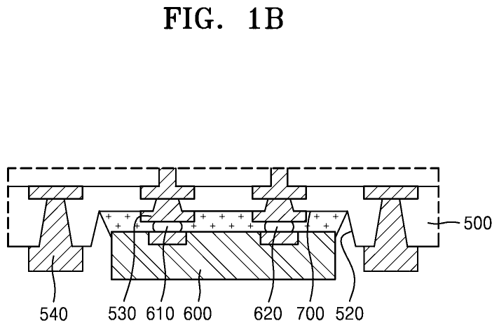

FIG. 1A is a cross-sectional view of a semiconductor package according to an embodiment, and FIG. 1B is an enlarged view of a region A of FIG. 1A.

Referring to FIGS. 1A and 1B, a semiconductor package 1000 according to the some example embodiment may include a first redistribution layer 100, a semiconductor device 200, a core layer 300, a sealing member 400, a substrate protection layer 500, and a passive device 600.

The first redistribution layer 100 may be disposed below the semiconductor device 200 and the core layer 300. The first redistribution layer 100 may redistribute the semiconductor device 200 mounted on the first redistribution layer 100, e.g., chip pads of the semiconductor device, to a region outside the semiconductor device 200. For example, the first redistribution layer 100 may include a first body insulation layer 110 and a first redistribution line 120. The first redistribution line 120 is formed to include multiple layers, and first redistribution lines 120 of different layers may be connected to each other through vias.

The first body insulation layer 110 may include, for example, an insulation material, e.g., photo imageable dielectric (PID) resin. Also, the first body insulation layer 110 may further include, for example, an inorganic filler. However, the material constituting the first body insulation layer 110 is not limited to the PID resin.

The first body insulation layer 110 may have a multiple layer structure according to the multiple layer structure of the first redistribution line 120. However, in FIG. 1A, for convenience of explanation, the first body insulation layer 110 is shown as a single layer structure. When the first body insulation layer 110 has a multiple layer structure, the first body insulation layer 110 may include, for example, a single material or at least two different materials.

The bottom surface of the first body insulation layer 110 may be covered by the substrate protection layer 500, and a first conductive pattern 510 may penetrate the substrate protection layer 500. The first conductive pattern 510 may be exposed to the outside from the substrate protection layer 500. For example, one end of the first conductive pattern 510 may be electrically connected to the first redistribution line 120 of the first redistribution layer 100, and the other end of the first conductive pattern 510 may be exposed to the outside, and accordingly an external connection terminal 150 may be disposed at the other end of the first conductive pattern 510. The external connection terminal 150 may be, for example, electrically connected to the semiconductor device 200 through the first conductive pattern 510 and the first redistribution line 120 of the first redistribution layer 100.

As shown in FIG. 1A, the first conductive pattern 510 and the external connection terminal 150 may be arranged on a virtual surface corresponding to the bottom surface of the semiconductor device 200. The virtual surface may be a surface that extends outwardly in a first direction (x direction) and a second direction (y direction). Accordingly, the first redistribution layer 100 may, for example, function to or be configured to redistribute a chip pad of the semiconductor device 200, e.g., of a semiconductor chip, as an external connection pad with a larger area than the bottom surface of the semiconductor chip. As such, a package structure in which the external connection terminal 150 is widely provided beyond the bottom surface of the semiconductor device 200 may be referred to as a fan-out (FO) package structure. On the other hand, a package structure in which the external connection terminal 150 is provided only on the bottom surface of the semiconductor device 200 may be referred to as a fan-in (FI) package structure.

The semiconductor device 200 may be disposed within a through-hole region defined (for example, at least partially defined) by the core layer 300. The through-hole region may be defined as a region inside (for example, defined or at least partially defined by) a through-hole TH that completely penetrates the core layer 300. The semiconductor device 200 may be, for example, disposed spaced apart from the inner wall of the through-hole TH, but example embodiments are not limited thereto.

The sealing member 400 may be disposed between an inner wall of the through-hole TH and the semiconductor device 200. The semiconductor device 200 may be mounted on the first redistribution layer 100 through a first connection terminal 210, for example mounted on the first redistribution layer 100 with a first connection terminal 210 therebetween. The first connection terminal 210 may include, for example, a pillar and/or solder, but example embodiments are not limited thereto. For example, according to some example embodiments, the first connection terminal 210 may include only solder.

The semiconductor device 200 may include, for example, at least one logic semiconductor chip and/or memory semiconductor chip. A logic semiconductor chip may include, for example, an application processor (AP), a microprocessor, a central processing unit (CPU), a controller, an application specific integrated circuit (ASIC), etc., but example embodiments are not limited thereto. A memory semiconductor chip may include, for example, a volatile memory like dynamic random access memory (DRAM) and static random access memory (SRAM) or a non-volatile memory like flash memory, but example embodiments are not limited thereto. In the semiconductor package 1000 according to the some example embodiments, the semiconductor device 200 may include, for example, a logic semiconductor chip, e.g., an AP chip. Also, for example, the semiconductor device 200 may be referred to as a system-on-chip (SoC) in terms of integrated functions. Hereinafter, for convenience of explanation, the semiconductor device 200 will be described as a semiconductor chip.

In the semiconductor package 1000 according to some example embodiments, the semiconductor device 200 may include a chip pad disposed on the bottom surface thereof. Therefore, the bottom surface of the semiconductor device 200, on which the chip pad is disposed, may be, for example, an active surface, and the top surface of the semiconductor device 200 opposite to the bottom surface of the semiconductor device 200 may be an inactive surface. The chip pad may be electrically connected to another component inside the semiconductor device 200, e.g., an integrated circuit. In more detail, multiple wiring layers, for example, may be formed on the bottom surface of the semiconductor device 200, and the chip pad may be electrically connected to an integrated circuit inside the semiconductor device 200 through the multiple wiring layers, but example embodiments are not limited thereto.

As shown in FIG. 1, the semiconductor device 200 may be mounted on the first redistribution layer 100 through the first connection terminal 210. Therefore, an integrated circuit of the semiconductor device 200 may be connected to the first redistribution line 120 of the first redistribution layer 100 through the first connection terminal 210 and may also be connected to the external connection terminal 150 through the first redistribution line 120. Since the bottom surface of the semiconductor device 200 may be an active surface, an active surface of the semiconductor device 200 may face the first redistribution layer 100 therebelow.

The core layer 300 may define (for example, at least partially define) the through-hole TH that completely penetrates the core layer 300. As described above, the semiconductor device 200 may be disposed in the through-hole TH of the core layer 300.

The core layer 300 may include a core insulation layer 310, a core wire 320u, 320d, and a core via 330. The core insulation layer 310 may maintain and/or support the overall structure of the semiconductor package 1000. Accordingly, due to the function of the core insulation layer 310, the core layer 300 may be referred to as a support member. In addition, the core layer 300 may include, for example, an embedded trace substrate (ETS) core, but example embodiments are not limited thereto. In the case of an ETS, for example, the number of wiring layers may be reduced by using prepreg, but example embodiments are not limited thereto.

The core insulation layer 310 may include, for example, an insulation material, e.g., thermosetting resin such as epoxy resin or thermoplastic resin such as polyimide, and may further include an inorganic filler, but example embodiments are not limited thereto. The core insulation layer 310 may also include, for example, resin impregnated into a core material such as glass fiber, glass cloth, and glass fabric together with an inorganic filler, e.g., prepreg, Ajinomoto build-up film (ABP), FR-4, Bismaleimide Triazine (BT), etc., but example embodiments are not limited thereto.

The core wire 320 may be formed in, for example, a multiple layer structure. Also, the core wire 320 may be, for example, divided into a lower core wire 320d disposed in the lower portion of the core insulation layer 310 and an upper core wire 320u disposed in the upper portion of the core insulation layer 310. The core via 330 may have a structure extending in the z direction and may connect the lower core wire 320d and the upper core wire 320u to each other. Also, in each of the lower core wire 320d and the upper core wire 320u, the core via 330 may connect wires of different layers to each other. In addition, the core insulation layer 310 may have a multiple layer structure corresponding to the multiple layer structure of the core wire 320, but example embodiments are not limited thereto. However, for convenience of explanation, the core insulation layer 310 is shown as a single layer in FIG. 1A.

The sealing member 400 may seal the semiconductor device 200 and reduce or prevent physical and/or chemical damage to the semiconductor device 200 from the outside. In more detail, the sealing member 400 may cover or at least partially cover the side surfaces and the top surface of the semiconductor device 200 and the top surface of the core layer 300. In other words, the sealing member 400 may fill or at least partially fill a space between the semiconductor device 200 and the inner wall of the through-hole TH and cover the top surface of the semiconductor device 200 and the top surface of the core layer 300. According to some example embodiments, the sealing member 400 may be formed to a have a small thickness on the top surface of the semiconductor device 200 and the top surface of the core layer 300 or may be omitted, but example embodiments are not limited thereto.

The sealing member 400 may include for example, thermosetting resin, such as epoxy resin, thermoplastic resin, such as polyimide, and/or resin containing a reinforcing material, such as an inorganic filler (e.g., ABF, FR-4, or BT resin, etc.), but example embodiments are not limited thereto. Also, the sealing member 400 may include, for example, a molding material, such as EMC, and/or a photosensitive material, such as photo-imageable encapsulant (PIE). However, the material or materials of the sealing member 400 are not limited to the above-stated materials.

A connection pad 430 may be disposed on the top surface of the sealing member 400. The connection pad 430 may be electrically connected to the core wire 320 of the core layer 300 through a via electrode 410.

A passivation layer 420 may be disposed on the top surface of the sealing member 400. The connection pad 430 may be exposed from (for example, not overlapping with) the passivation layer 420. According to some example embodiments, the upper portion of the sealing member 400, in which the via electrode 410 and the connection pad 430 are arranged, may be considered as a redistribution layer.

As a bump may be disposed on the connection pad 430 and at least one upper package may be disposed on the semiconductor package 1000 through the bump, a Package-On-Package (POP) structure may be implemented, but example embodiments are not limited thereto.

The substrate protection layer 500 may be disposed on the bottom surface of the first redistribution layer 100 to protect the first redistribution layer 100. The substrate protection layer 500 may include, for example, an insulation material, e.g., a build-up film containing resin or a SiOx filler such as ABF, but example embodiments are not limited thereto.

The substrate protection layer 500 may have an opening that exposes a portion of a first redistribution line 120a. The opening of the substrate protection layer 500 may be formed, for example, through laser processing, but example embodiments are not limited thereto.

The first conductive pattern 510 may be formed in an opening of the substrate protection layer 500. The first conductive pattern 510 may be electrically connected to the first redistribution line 120a through the opening of the substrate protection layer 500. The first conductive pattern 510 may be, for example, an under bump metallurgy (UBM) structure. According to some example embodiments, a UBM structure may include, for example, three conductive material layers, e.g., a titanium layer, a copper layer, and a nickel layer. However, example embodiments are not limited thereto, and there may be numerous suitable materials and arrangements of layers suitable for forming an UBM structure, such as, for example, a chromium/chromium copper alloy/copper/gold arrangement, a titanium/titanium tungsten/copper arrangement, or a copper/nickel/gold arrangement. Any suitable materials or material layers that may be used for a UBM structure may be fully encompassed within the scope of inventive concepts.

The external connection terminal 150 is disposed on the bottom surface of the first conductive pattern 510 and may be electrically connected to the first redistribution line 120a through the first conductive pattern 510. The external connection terminal 150 may connect the semiconductor package 1000 to, for example, a main board of an electronic device on which the semiconductor package 1000 is mounted. The external connection terminal 150 may include, for example, a conductive material, e.g., at least one of solder, tin (Sn), silver (Ag), copper (Cu), and aluminum (Al), but example embodiments are not limited thereto.

The passive device 600 may be disposed within a groove 520 of (for example, defined or at least partially defined by) the substrate protection layer 500. The groove 520 may be formed by removing a portion of the lower portion of the substrate protection layer 500. The passive device 600 may be arranged to be spaced apart from an inner wall of the groove 520.

The passive device 600 may include, for example, a Si-capacitor. The Si-capacitor may include, for example, an integrated stack capacitor (ISC), but example embodiments are not limited thereto.

The passive device 600 may be mounted on the substrate protection layer 500 within the groove 520 through a second connection terminal 620. The second connection terminal 620 may electrically interconnect a device pad 610 of the passive device 600 to a second conductive pattern 530 within the groove 520. The second connection terminal 620 may be, for example, a bump, but example embodiments are not limited thereto.

An underfill 700 may fill the space between (for example, defined or at least partially defined by) the passive device 600 and the substrate protection layer 500 and between connection terminals 620, within the groove 520. In other words, the groove 520 may prevent or hinder the underfill 700 from invading the first conductive pattern 510 around the outside of the passive device 600. In more detail, the underfill 700 may have low flowability on photo imageable dielectric (PID) resin due to the characteristics of the material constituting the underfill 700, but may overflow due to high flowability on a material containing, for example, SiOx fillers, such as ABF. When the substrate protection layer 500 contains SiOx fillers as in some example embodiments, the underfill 700 may overflow on the substrate protection layer 500 and spread around the passive device 600. According to some example embodiments of inventive concepts, the groove 520 may be formed in the substrate protection layer 500, and the underfill 700 may fill the space between the passive device 600 and the substrate protection layer 500 within the groove 520, thereby preventing or hindering the underfill 700 from flowing to another first conductive pattern 510 around the passive device 600.

A dam 540 may be spaced apart from the passive device 600 and protrude on the substrate protection layer 500 to surround (for example, at least partially surround) the passive device 600. In detail, the dam 540 may surround or at least partially surround the passive device 600 while being spaced apart from the passive device 600 at the outermost portion of the groove 520.

The dam 540 may include, for example, the same material as the first conductive pattern 510 and may be formed through the same process, but example embodiments are not limited thereto.

The dam 540 may have, for example, a height greater than that of the first conductive pattern 510. In other words, the height of the dam 540 protruding from the bottom surface of the substrate protection layer 500 may be greater than the height of the first conductive pattern 510 protruding from the bottom surface of the substrate protection layer 500. According to some example embodiments, the height of the dam 540 may not reach the bottom surface of the passive device 600 disposed in the groove 520. In other words, the height of the dam 540 protruding from the bottom surface of the substrate protection layer 500 may be less than a distance from the bottom surface of the substrate protection layer 500 defining the groove 520 to one surface of the passive device 600 that is farthest away from the bottom surface of substrate protection layer 500 defining the groove 520, but example embodiments are not limited thereto.

The dam 540 may be formed to be spaced outwardly (for example, spaced apart) from the passive device 600 and to surround or at least partially surround the passive device 600 in the groove 520, thereby hindering or preventing the underfill 700 disposed between the passive device 600 and the substrate protection layer 500 from overflowing. As described above, the overflow of the underfill 700 may be hindered or blocked by the groove 520. However, when the underfill 700 flows over the groove 520, the overflow of the underfill 700 beyond the groove 520 may be hindered or blocked by the dam 540.

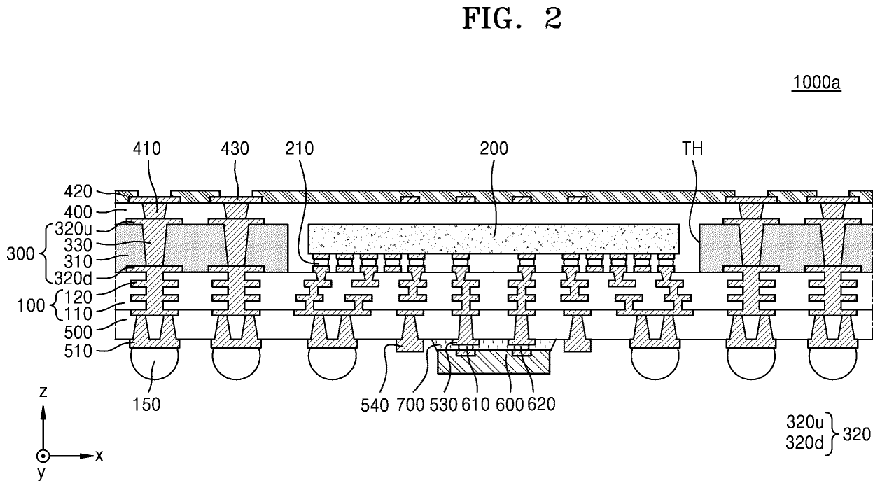

FIG. 2 is a cross-sectional view of a semiconductor package according to some example embodiments. Descriptions already given above with reference to FIGS. 1A and 1B are briefly given or omitted.

Referring to FIG. 2, unlike the semiconductor package 1000 of FIG. 1A, in a semiconductor package 1000a according to example embodiments, overflow of the underfill 700 may be hindered or blocked only by the dam 540 without the groove 520 in the semiconductor package 1000a. In more detail, in the semiconductor package 1000a according to example embodiments, the groove 520 may not formed in the substrate protection layer 500, and the passive device 600 may be disposed on the bottom surface of the substrate protection layer 500. The first conductive pattern 510 and the second conductive pattern 530 formed on the substrate protection layer 500 may both be formed on the same plane, for example, the bottom surface of the substrate protection layer 500, the external connection terminal 150 may be disposed on the first conductive pattern 510, and the passive device 600 may be disposed on the second conductive pattern 530 through the second connection terminal 620.

The semiconductor package 1000a according to example embodiments may include the dam 540 protruding from the substrate protection layer 500 to surround or at least partially surround the passive device 600 and to be spaced apart from the passive device 600.

The dam 540 may be formed outside the passive device 600 to hinder or prevent the underfill 700 disposed between the passive device 600 and the substrate protection layer 500 from overflowing.

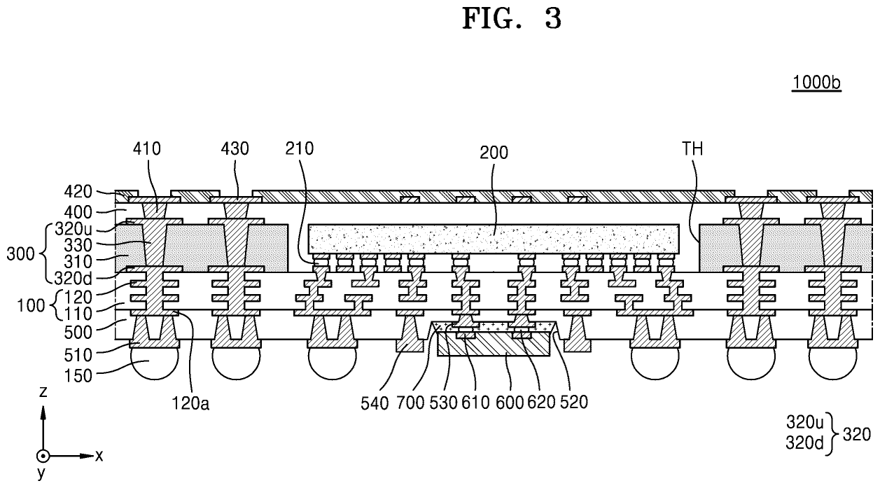

FIG. 3 is a cross-sectional view of a semiconductor package according to some r example embodiments. Descriptions already given above with reference to FIGS. 1A to 2 are briefly given or omitted.

Referring to FIG. 3, unlike the semiconductor package 1000 of FIG. 1A, in a semiconductor package 1000b according to some example embodiments, overflow of the underfill 700 may be hindered or blocked only by the groove 520 without the dam 540 in the semiconductor package 1000b. In more detail, in the semiconductor package 1000b according some example embodiments, the groove 520 may be formed in the substrate protection layer 500, and the dam 540 may not formed around the groove 520. The second conductive pattern 530 may be formed on one surface of the substrate protection layer 500 within the groove 520, and the passive device 600 may be disposed on the second conductive pattern 530 through the second connection terminal 620.

The depth of the groove 520 may be, for example, greater than a distance from the bottom surface of the groove 520 to the second connection terminal 620, which may be, for example, a bump. In other words, the depth of the groove 520 may be greater than the distance from the bottom surface of the groove 520 to one surface of the passive device 600 contacting a bump 610, but example embodiments are not limited thereto.

The underfill 700 may be disposed between the passive device 600 and the substrate protection layer 500 within the groove 520, and the groove 520 may hinder or prevent the underfill 700 from overflowing.

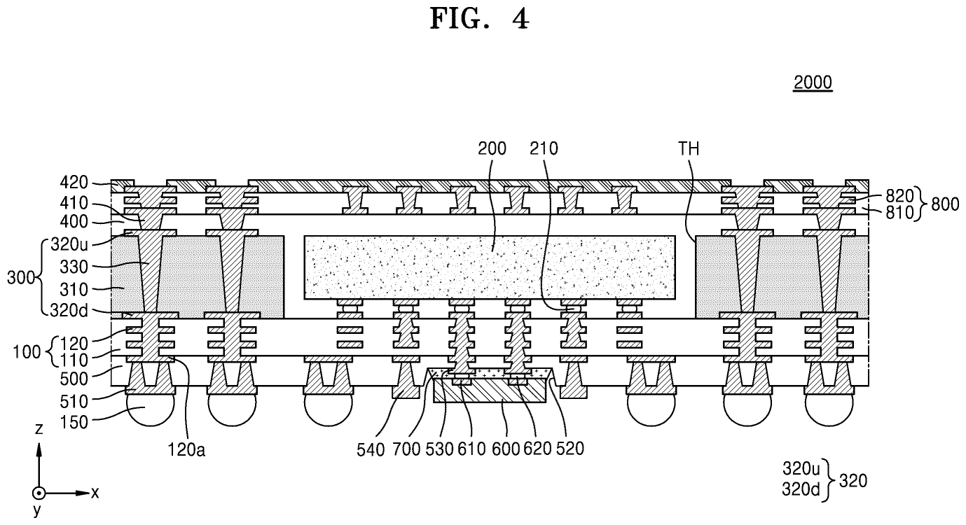

FIG. 4 is a cross-sectional view of a semiconductor package according to some example embodiments. Descriptions already given above with reference to FIGS. 1A to 3 are briefly given or omitted.

Referring to FIG. 4, unlike the semiconductor package 1000 of FIG. 1A, a semiconductor package 2000 according to some example embodiments may further include a second redistribution layer 800. In more detail, in the semiconductor package 2000 according to some example embodiments, the second redistribution layer 800 may be disposed on the sealing member 400. The second redistribution layer 800 may be electrically connected to the via electrode 410 of the sealing member 400.

The second redistribution layer 800 may include, for example, a second body insulation layer 810 and a second redistribution line 820. The second redistribution line 820 may be formed as, for example, multiple layers, and second redistribution lines 820 of different layers may be connected to one another through vias. The structures and the materials of the second body insulation layer 810 and the second redistribution line 820 may be identical to those of the first body insulation layer 110 and the first redistribution line 120 of the semiconductor package 1000 of FIG. 1 described above, but example embodiments are not limited thereto.

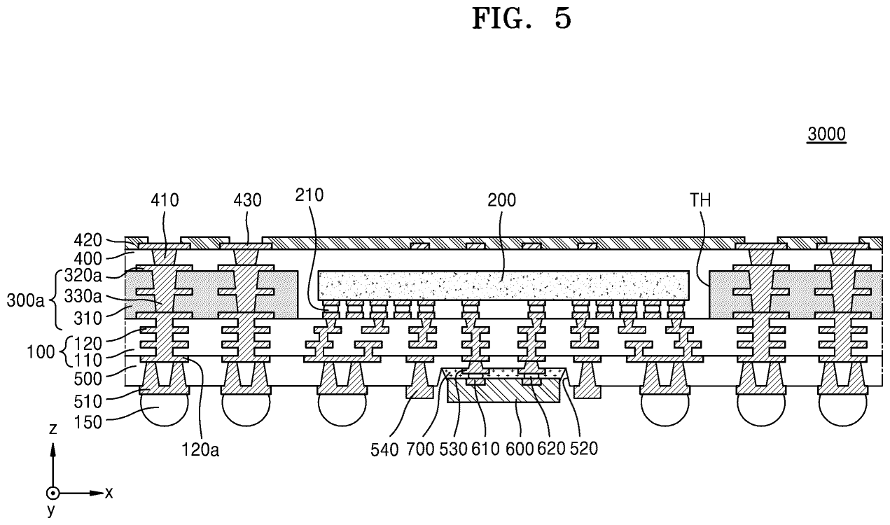

FIG. 5 is a cross-sectional view of a semiconductor package according to some example embodiments. Descriptions already given above with reference to FIGS. 1A to 4 are briefly given or omitted.

Referring to FIG. 5, a semiconductor package 3000 according to some example embodiments may be different from the semiconductor package 1000 of FIG. 1A in terms of the structure of a core wire 320a of a core layer 300a. In more detail, in the semiconductor package 3000 according to some example embodiments, the core layer 300a may include the core insulation layer 310, the core wire 320a, and a core via 330a. The core wire 320a may be formed as, for example, a multiple layer structure. The core via 330a may connect core wires 320a of different layers to each other. In addition, the core wire 320a may be divided into an upper core wire, a lower core via, and a lower core wire and may also be disposed in the middle portion of the core insulation layer 310. Also, the core via 330a may have a relatively small length and may connect the core wires 320a of different layers to each other.

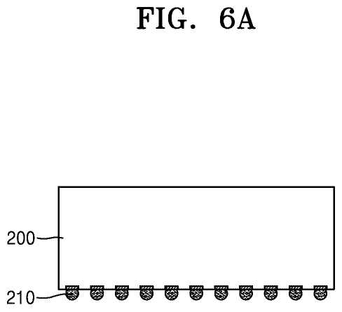

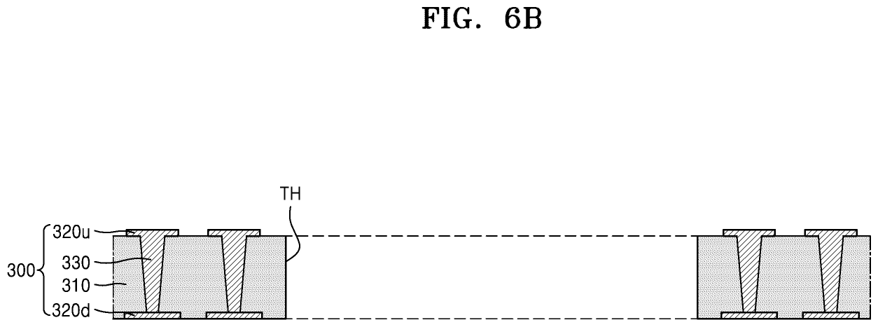

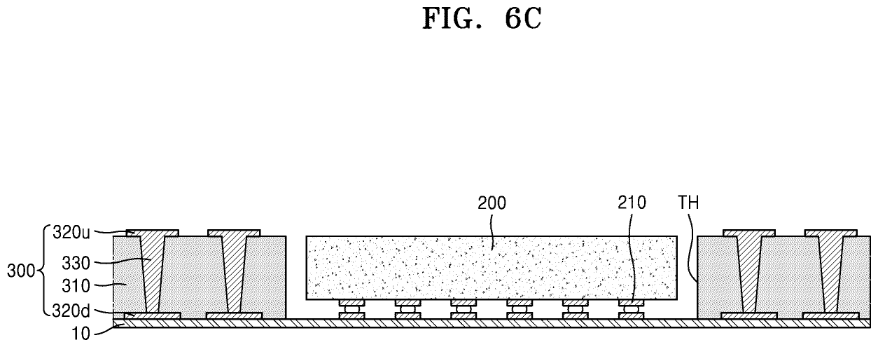

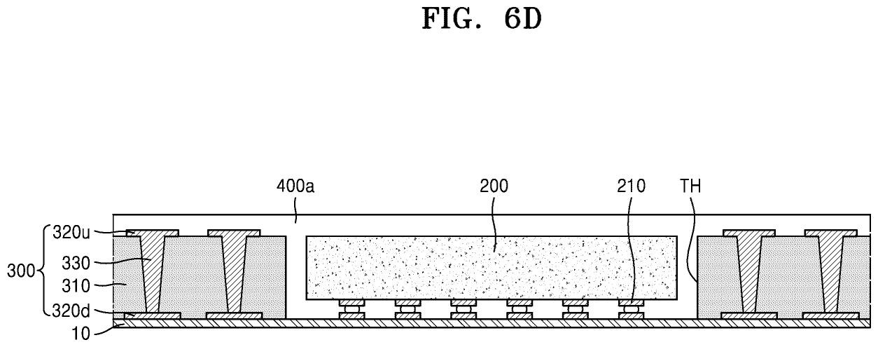

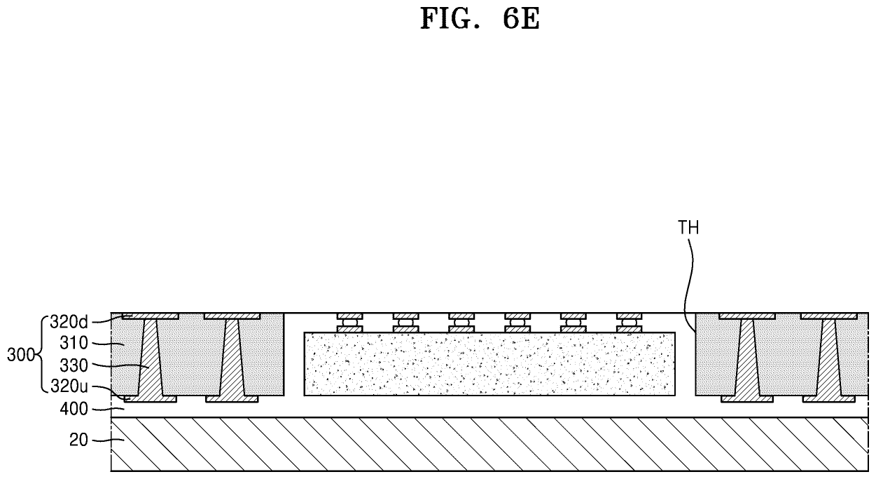

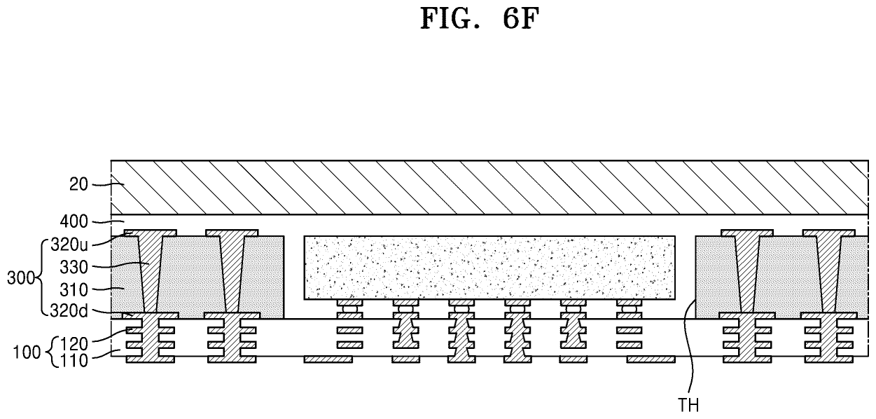

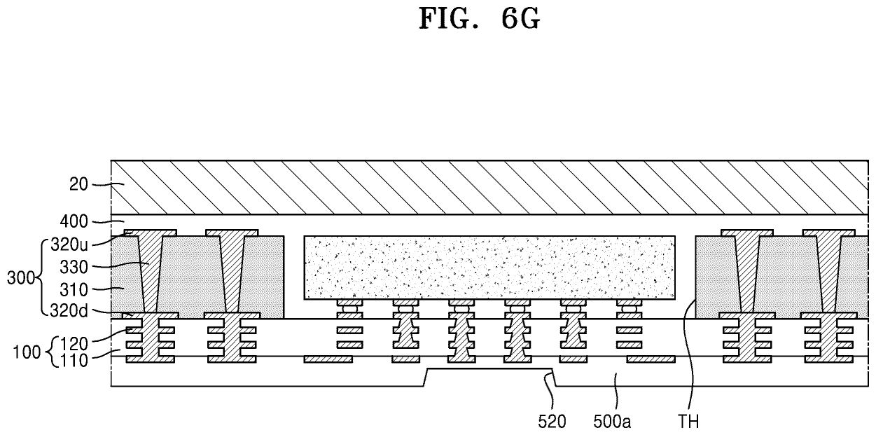

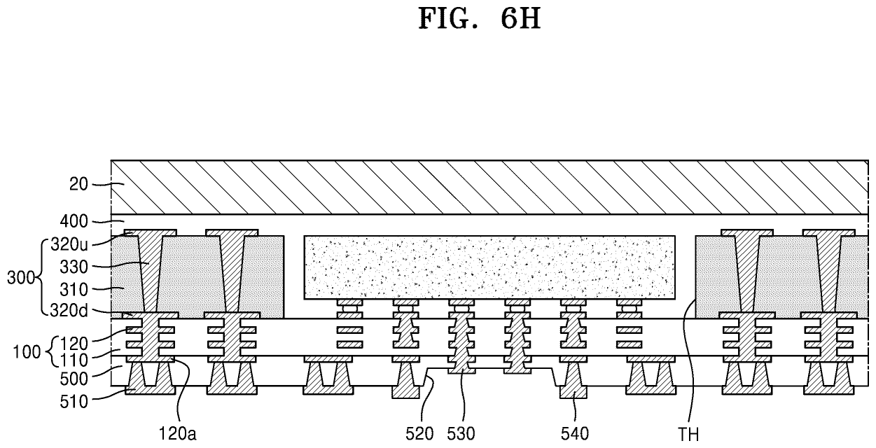

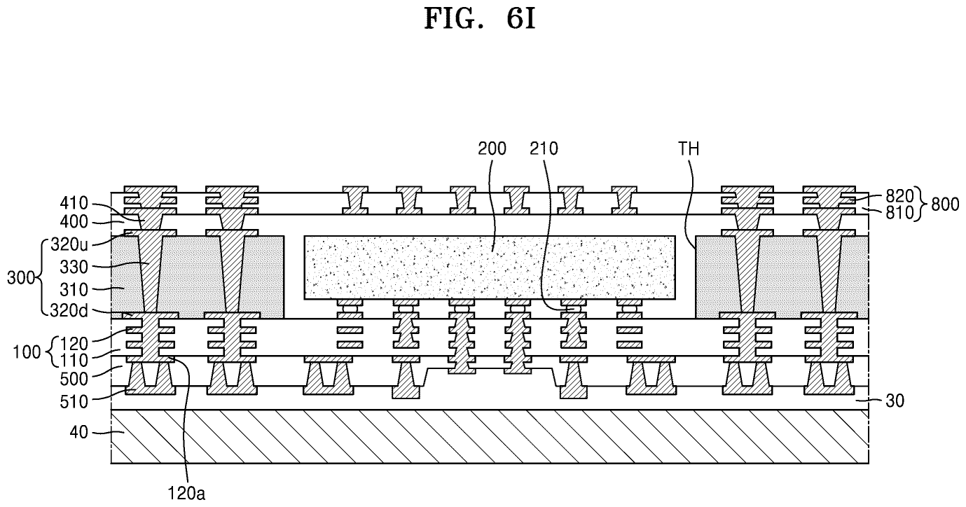

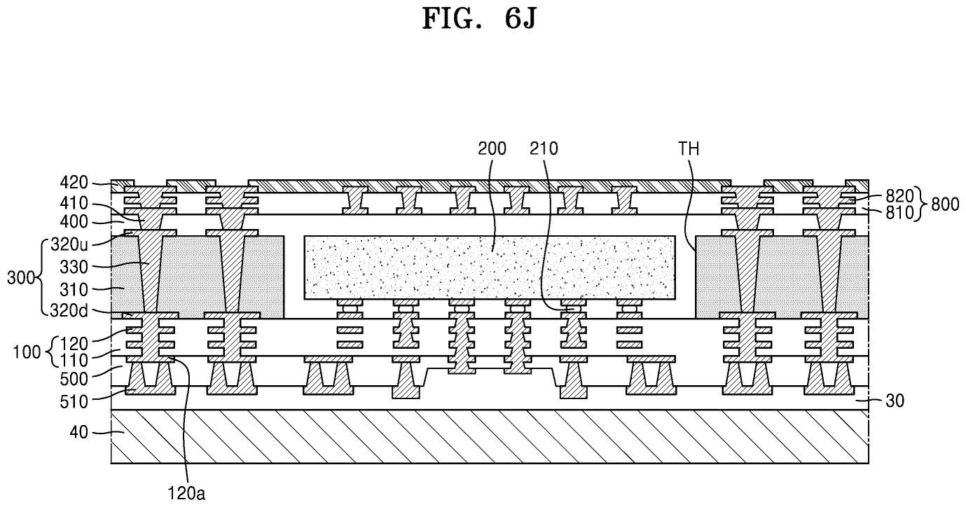

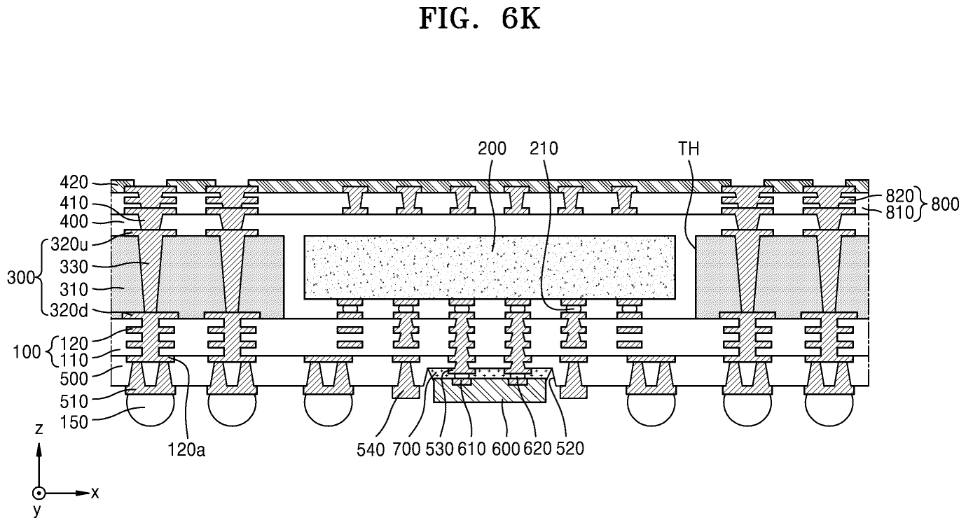

FIGS. 6A to 6K are schematic plan views of operations of a method of manufacturing a semiconductor package, according to some example embodiments. Descriptions of FIGS. 6A to 6K are given below with reference to FIG. 1A, and descriptions already given above with reference to FIGS. 1A to 5 are briefly given or omitted.

Referring to FIG. 6A, in the method of manufacturing a semiconductor package according to the present some example embodiments, first, the semiconductor device 200 is prepared. The semiconductor device 200 may correspond to the semiconductor device 200 of the semiconductor package 1000 of FIG. 1.

As shown in FIG. 6A, connection terminals may be arranged on an active surface of the semiconductor device 200. In more detail, the first connection terminal 210 may be disposed on the bottom surface, which may be the active surface, of the semiconductor device 200.

Referring to FIG. 6B, after the semiconductor device 200 is prepared, the core layer 300 may be formed. In more detail, first, an initial core layer may be formed on a carrier substrate. For example, a plurality of insulation layers constituting the core insulation layer 310 may be formed on a carrier substrate, and core vias 330 penetrating through the respective insulation layers and core wires 320 on the respective insulation layers may be formed, thereby forming the initial core layer.

Subsequently, the through-hole TH may be formed through the core insulation layer 310. The size and the shape of the through-hole TH may be determined according to the size and the shape of the semiconductor device 200 to be placed therein. The through-hole TH may be formed through, for example, mechanical drilling and/or laser drilling. Alternatively or additionally, the through-hole TH may be formed by a sand blasting method using abrasive particles or a dry etching method using plasma, but example embodiments of forming the through-hole TH are not limited to the above-mentioned methods.

The core layer 300 may be formed by forming the through-hole TH in the core insulation layer 310.

Referring to FIG. 6C, after the core layer 300 is formed, the semiconductor device 200 may be placed in the through-hole TH. The semiconductor device 200 may be disposed in the through-hole TH such that the bottom surface, which may be the active surface, of the semiconductor device 200 faces downward.

Moreover, a support tape 10 may be disposed on the bottom surface of the through-hole TH, and the semiconductor device 200 may be disposed within the through-hole TH as the first connection terminal 210 is attached to the support tape 10.

Referring to FIG. 6D, after the semiconductor device 200 is disposed on the core layer 300, the sealing member 400 may be disposed on the core layer 300. The sealing member 400 may fill (for example, entirely fill or at least partially fill) the space between the semiconductor device 200 and inner walls of the through-hole TH and cover the top surface of the semiconductor device 200 and the top surface of the core layer 300. According to some example embodiments, the sealing member 400 may be formed to have a small thickness on the top surface of the semiconductor device 200 and the top surface of the core layer 300 may be omitted, but example embodiments are not limited thereto.

Referring to FIG. 6E, a first carrier substrate 20 may be attached to the sealing member 400, and the support tape 10 attached to the bottom surface of the through-hole TH may be removed.

Referring to FIG. 6F, the first redistribution layer 100 may be formed on the core layer 300 and the semiconductor device 200. The first redistribution layer 100 may be formed by sequentially forming a plurality of first body insulation layers 110 and forming the first redistribution line 120 and a via on each of the first body insulation layers 110.

Referring to FIG. 6G, after the first redistribution layer 100 is formed, a substrate protection layer 500a may be formed on the first redistribution layer 100. The substrate protection layer 500a may include, for example, an insulation material, e.g., a build-up film containing resin or a SiOx filler such as ABF, but example embodiments are not limited thereto. The groove 520 may be formed in the substrate protection layer 500a. The groove 520 may be formed through, for example, laser processing, but example embodiments are not limited thereto.

Referring to FIG. 6H, after the groove 520 is formed in the substrate protection layer 500a, an opening may be formed in the substrate protection layer 500a to expose the first redistribution line 120a below the substrate protection layer 500. The opening of the substrate protection layer 500 may be formed through, for example, the laser processing for forming the groove 520. In other words, the depth of the laser processing may be adjusted to form an opening and the groove 520 in the substrate protection layer 500.

The first conductive pattern 510 may be formed in the opening of the substrate protection layer 500. The first conductive pattern 510 may be electrically connected to the first redistribution line 120a through the opening of the substrate protection layer 500. As described above, the first conductive pattern 510 may be, for example, a UBM structure. UBM structures may be formed, for example, by forming a seed layer inside the opening of the substrate protection layer 500 and on the substrate protection layer 500, forming a patterned mask layer (e.g., a photoresist layer) on the seed layer, forming a conductive material(s) inside openings of the patterned mask layer and on the seed layer (e.g., by plating), removing the patterned mask layer, and removing portions of the seed layer without the conductive material(s). However, example embodiments are limited thereto, and other methods may be used to form UBM structures.

The dam 540 may be formed to be spaced apart from the groove 520. The dam 540 may be formed to surround or at least partially surround the groove 520.

The dam 540 may be, for example, formed of the same material and in the same process as the first conductive pattern 510. The dam 540 may be formed to have, for example, a height greater than that of the first conductive pattern 510. The dam 540 may or may not, for example, be electrically connected to the first redistribution layer 100 and may hinder or prevent the underfill 700 from overflowing.

Referring to FIG. 6I, after the first conductive pattern 510 and the dam 540 are formed, a protective layer 30 may be placed on the substrate protection layer 500, and a second carrier substrate 40 may be placed on the protective layer 30.

The second redistribution layer 800 may be formed on the sealing member 400 facing the second carrier substrate 40. The second redistribution layer 800 may be formed by, for example, sequentially forming a plurality of second body insulation layers 810 and forming the second redistribution line 820 and a via on each of the second body insulation layers 810.

Referring to FIG. 6J, after the second redistribution layer 800 is formed, the passivation layer 420 may be formed on the second redistribution layer 800. An opening may be formed in the passivation layer 420 to expose the second redistribution line 820.

Referring to FIG. 6K, the protective layer 30 and the second carrier substrate 40 may be removed to expose the first conductive pattern 510 and the groove 520, and the passive device 600 may be mounted in the groove 520.

After the passive device 600 is mounted in the groove 520, the space between the passive device 600 and the substrate protection layer 500 and the space between the connection terminals 620 within the groove 520 may be filled with the underfill 700. The groove 520 and the dam 540 formed around the groove 520 may hinder or prevent the underfill 700 from overflowing onto the first conductive pattern 510 around the passive device 600.

While inventive concepts have been particularly shown and described with reference to example embodiments thereof, it will be understood by one ordinarily skilled in the art that various changes in form and details may be made therein without departing from the spirit and scope of the following claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

What is claimed is:

1. A semiconductor package comprising:
a first redistribution layer;
a semiconductor device on the first redistribution layer;
a substrate protection layer below the first redistribution layer;
a groove defined by a bottom surface of the substrate protection layer;
a passive device in the groover;
an underfill between the passive device and the groove; and
a dam apart from the passive device, the dam protruding from the substrate protection layer and at least partially surrounding the passive device.

2. The semiconductor package of claim 1, further comprising:
a support member defining a through-hole and surrounding side surfaces of the semiconductor device; and
a sealing member in the through-hole and covering the semiconductor device.

3. The semiconductor package of claim 2, wherein the support member includes a core via that completely penetrates the support member and is electrically connected to the first redistribution layer.

4. The semiconductor package of claim 3, wherein the sealing member covers an upper portion of the support member and includes a via electrode electrically connected to the first redistribution layer through the core via.

5. The semiconductor package of claim 3, further comprising:
a second redistribution layer on the sealing member,
wherein the second redistribution layer is electrically connected to the first redistribution layer through the core via.

6. The semiconductor package of claim 1, wherein
the substrate protection layer includes a SiOx filler, and
the passive device includes a silicon capacitor.

7. The semiconductor package of claim 1, wherein a height of the dam is less than a height of the passive device.

8. The semiconductor package of claim 1, further comprising:
a first conductive pattern on the substrate protection layer and electrically connected to the first redistribution layer;
a second conductive pattern on a bottom surface of the substrate protection layer defining the groove; and
an external connection terminal on the first conductive pattern,
wherein a height of a portion of the dam that protrudes from the bottom surface of the substrate protection layer is
greater than a height of the first conductive pattern that protrudes from the bottom surface of the substrate protection layer, and
less than a distance from the bottom surface of the substrate protection layer defining the groove to a surface of the passive device that is farthest away from the bottom surface of substrate protection layer defining the groove.

9. The semiconductor package of claim 8, wherein the dam and the first conductive pattern include a same metal.

10. The semiconductor package of claim 8, wherein a bump is in the groove and between the passive device and the second conductive pattern.

11. A semiconductor package comprising:
a first redistribution layer;
a semiconductor device on the first redistribution layer;
a substrate protection layer below the first redistribution layer;
a groove defined by a bottom surface of the substrate protection layer;
a passive device in the groove; and
an underfill between the passive device and the groove.

12. The semiconductor package of claim 11, further comprising:
a first conductive pattern on a bottom surface of the substrate protection defining the groove and electrically connected to the first redistribution layer; and
a bump electrically connected to the first conductive pattern and the passive device,
wherein a depth of the groove is greater than a distance from the bottom surface of the groove to a surface of the passive device in contact with the bump.

13. The semiconductor package of claim 11, wherein
the substrate protection layer includes a SiOx filler, and
the passive device includes a silicon capacitor.

14. The semiconductor package of claim 11, further comprising:
a dam apart from the passive device, the dam protruding from the substrate protection layer and at least partially surrounding the passive device.

15. The semiconductor package of claim 14, further comprising:
a second conductive pattern on the substrate protection layer and electrically connected to the first redistribution layer; and
an external connection terminal on the second conductive pattern,
wherein a height of a portion of the dam that protrudes from the bottom surface of the substrate protection layer is
greater than a height of the second conductive pattern that protrudes from the bottom surface of the substrate protection layer, and
less than a distance from the bottom surface of the substrate protection layer defining the groove to a surface of the passive device that is farthest away from the bottom surface of substrate protection layer defining the groove.

16. The semiconductor package of claim 15, wherein the dam and the second conductive pattern include a same metal.

17. A semiconductor package comprising:
a first redistribution layer;
a semiconductor device on the first redistribution layer;
a support member defining a through-hole region wherein the semiconductor device is located;
a sealing member in the through-hole region and covering the semiconductor device;
a substrate protection layer below the first redistribution layer;
a groove defined by a bottom surface of the substrate protection layer;
a passive device in the groove;
an underfill between the passive device and the groove; and
a dam apart from the passive device, the dam protruding from the substrate protection layer and at least partially surrounding the passive device.

18. The semiconductor package of claim 17, wherein the substrate protection layer includes a SiOx filler.

19. The semiconductor package of claim 17, further comprising:
a conductive pattern on the substrate protection layer and electrically connected to the first redistribution layer,
wherein a height of a portion of the dam that protrudes from the bottom surface of the substrate protection layer is greater than a height of a portion of the conductive pattern that protrudes from the bottom surface of the substrate protection layer.

20. The semiconductor package of claim 17, further comprising a second redistribution layer on a sealing member.
